(19) United States
(12) Patent Application Publication
(10) Pub. No.: US 2024/0379386 A1
(43) Pub. Date: Nov. 14, 2024

(54) SUBSTRATE CLEANING APPARATUS, SUBSTRATE PROCESSING SYSTEM INCLUDING THE SAME AND METHOD OF PROCESSING SUBSTATE USING THE SAME

(71) Applicant: SAMSUNG ELECTRONICS CO., LTD., Suwon-si (KR)

(72) Inventors: YONGSUK CHOI, Suwon-si (KR); Ilkyu Jeong, Suwon-si (KR); Hyunwoong Hwang, Suwon-si (KR); Kyung-Won Kang, Suwon-si (KR); Dong-Wook Kim, Suwon-si (KR); Seok Heo, Suwon-si (KR)

(21) Appl. No.: 18/402,844

(22) Filed: Jan. 3, 2024

(30) Foreign Application Priority Data
May 10, 2023 (KR) 10-2023-0060401

(51) Int. Cl. H01L 21/67; H01L 21/677

(52) U.S. Cl. CPC H01L 21/67051; H01L 21/67751

(57) ABSTRACT

A substrate processing system includes a cluster module having substrate processing devices, a load port through which a substrate is loaded, and a substrate cleaning device between the cluster module and the load port, the substrate cleaning device being configured to clean the substrate processed in the substrate processing devices, and the substrate cleaning device including a substrate cleaner having a cleaning chuck to support the substrate, and a cleaning nozzle configured to spray a fluid toward the cleaning chuck.

### CROSS-REFERENCE TO RELATED APPLICATIONS

This U.S. non-provisional patent application claims priority under 35 U.S.C. § 119 to Korean Patent Application No. 10-2023-0060401, filed on May 10, 2023, in the Korean Intellectual Property Office, the entire contents of which are hereby incorporated by reference.

### BACKGROUND

### 1. Field

The present disclosure relates to a substrate cleaning apparatus, a substrate processing system including the same, and a method of processing a substrate using the same, and more particularly, to a substrate cleaning apparatus capable of transferring a substrate after cleaning the substrate that has passed through a substrate process apparatus, a substrate processing system and a method of processing a substrate using the same.

### 2. Description of the Related Art

Semiconductor devices may be manufactured through various processes. For example, a manufacturing of a semiconductor device may include a photo process, an etching process, a deposition process, and a plating process, for a substrate. After processing the substrate, contaminants, e.g., particles, may be generated on the substrate. A cleaning process may be performed to remove the contaminants from the substrate, e.g., via a substrate cleaning device.

### SUMMARY

A substrate processing system according to some embodiments of the present disclosure may include a load port through which a substrate is loaded and a substrate cleaning device configured to clean the substrate processed in the substrate processing device, the substrate cleaning device may include a substrate cleaning unit, the substrate cleaning unit may include a cleaning chuck and a cleaning nozzle spraying a fluid to the substrate on the cleaning chuck, and the substrate cleaning device may be located between the cluster module and the load port.

A substrate processing system with a substrate cleaning apparatus according to some embodiments of the present disclosure may include a substrate cleaning unit, a liquid supply device supplying DIW to the substrate cleaning unit, and a gas supply device supplying gas to the substrate cleaning unit, the substrate cleaning unit may include a cleaning chuck supporting a substrate and a lower cleaning nozzle spraying fluid to the substrate on the cleaning chuck, the gas supply device may include a nitrogen supply device connected to the lower cleaning nozzle and supplying nitrogen to the lower cleaning nozzle and a carbon dioxide supply device connected to the lower cleaning nozzle and supplying carbon dioxide to the lower cleaning nozzle.

A method of processing a substrate according to some embodiments of the present disclosure may include processing a substrate in a substrate processing device, cleaning the substrate in a substrate cleaning device before the substrate processed in the substrate processing device is loaded on a load port spaced from the substrate processing device, and loading the substrate cleaned in the substrate cleaning device on the load port, the substrate cleaning device may include a substrate cleaning unit configured to clean the substrate by spraying a fluid to the substrate, the substrate cleaning unit may include a cleaning chuck supporting the substrate and a lower cleaning nozzle spraying the fluid toward the substrate on the cleaning chuck, and the substrate cleaning device may be located between the substrate processing device and the load port.

### BRIEF DESCRIPTION OF THE DRAWINGS

Features will become apparent to those of skill in the art by describing in detail exemplary embodiments with reference to the attached drawings, in which:

FIG. 1 is a schematic diagram illustrating a substrate processing system according to embodiments of the present disclosure.

FIG. 2 is a perspective view illustrating a substrate cleaning device according to embodiments of the present disclosure.

FIG. 3 is a perspective view illustrating a portion of a substrate cleaning device according to embodiments of the present disclosure.

FIG. 4 is a perspective view illustrating a portion of a substrate cleaning device according to embodiments of the present disclosure.

FIG. 5 is a perspective view illustrating a substrate cleaning unit according to embodiments of the present disclosure.

FIG. 6 is an exploded perspective view illustrating a substrate cleaning unit according to embodiments of the present disclosure.

FIG. 7 is an exploded perspective view illustrating a portion of a substrate cleaning unit according to embodiments of the present disclosure.

FIG. 8 is an exploded perspective view illustrating a portion of a substrate cleaning unit according to embodiments of the present disclosure.

FIG. 9 is an exploded perspective view illustrating a portion of a substrate cleaning unit according to embodiments of the present disclosure.

FIG. 10 is an exploded perspective view illustrating a portion of a substrate cleaning unit according to embodiments of the present disclosure.

FIG. 11 is an exploded perspective view illustrating a portion of a substrate cleaning unit according to embodiments of the present disclosure.

FIG. 12 is a cross-sectional view illustrating a portion of a substrate cleaning unit according to embodiments of the present disclosure.

FIG. 13 is a cross-sectional view illustrating a portion of a substrate cleaning unit according to embodiments of the present disclosure.

FIG. 14 is a cross-sectional view illustrating a substrate processing device according to embodiments of the present disclosure.

FIG. 15 is a perspective view illustrating a substrate processing device according to embodiments of the present disclosure.

FIG. 16 is a flowchart illustrating a method of processing a substrate according to embodiments of the present disclosure.

FIGS. 17 to 21 are diagrams illustrating stages in a method of processing a substrate according to the flowchart of FIG. 16.

### DETAILED DESCRIPTION

Hereinafter, embodiments of the present disclosure will be described with reference to the accompanying drawings. Like reference numbers throughout the specification may refer to like elements.

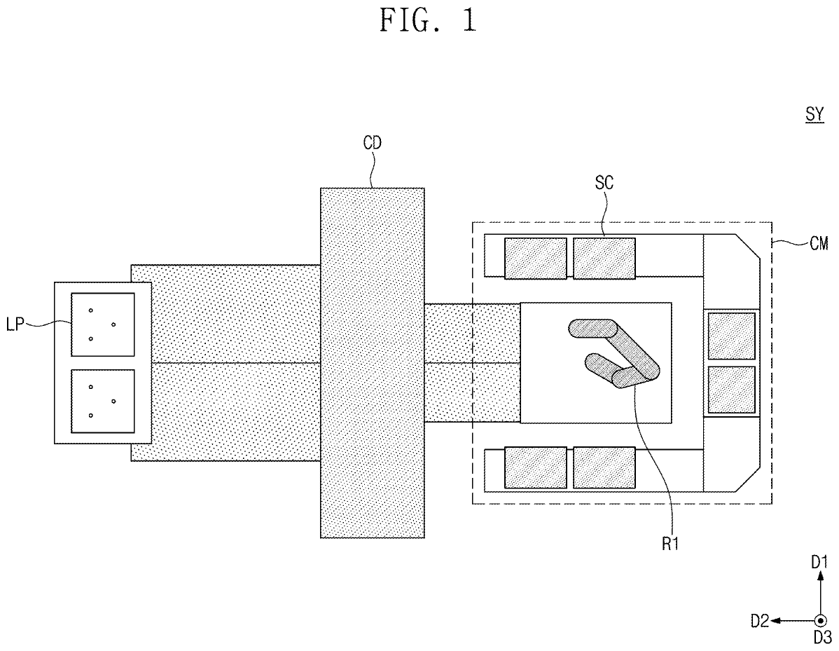

FIG. 1 is a schematic diagram illustrating a substrate processing system according to embodiments of the present disclosure.

Hereinafter, D1 may be referred to as a first direction, D2 may be referred to as a second direction crossing the first direction D1, and D3 may be referred to as a third direction crossing each of the first and second directions D1 and D2. Each of the first direction D1 and the second direction D2 may be referred to as a horizontal direction. Also, the third direction D3 may be referred to as a vertical direction or an upward direction.

Referring to FIG. 1, a substrate processing system SY may be provided. The substrate processing system SY may perform various processes on a substrate. For example, the substrate processing system SY may perform a deposition process, an etching process, a polishing process, a cleaning process, and/or a photo process on the substrate. For example, the term ‘substrate’ used herein may refer to a silicon (Si) wafer. The substrate processing system SY may include a cluster module CM, a substrate cleaning device CD, and a load port LP.

The cluster module CM may include a substrate processing device SC and a main transfer robot R1. The substrate processing device SC may be a chamber that processes a substrate. For example, the substrate processing device SC may include at least one of an etching chamber, a polishing chamber, and a deposition chamber. The cluster module CM may include a plurality of substrate processing devices SC. Each of the plurality of substrate processing devices SC may face the main transfer robot R1. The main transfer robot R1 may be located at a center of the plurality of substrate processing devices SC. The main transfer robot R1 may transfer substrates between each of the plurality of substrate processing devices SC. Hereinafter, for convenience, the substrate processing device SC will be described in the singular. The main transfer robot R1 may transfer the substrate on the load port LP to the substrate processing device SC. The main transfer robot R1 may transfer the substrate processed in the substrate processing device SC to the substrate cleaning device CD, e.g., the main transfer robot R1 may transfer the substrate processed in the substrate processing device SC to the substrate cleaning unit CU of the substrate cleaning device CD. For example, the main transfer robot R1 may include a plurality of arms. In another example, the main transfer robot R1 may include other types of moving mechanisms.

The substrate cleaning device CD may clean the substrate. In detail, the substrate cleaning device CD may clean the substrate processed by the substrate processing device SC. The substrate cleaned by the substrate cleaning device CD may be transferred to the load port LP. The substrate cleaning device CD may be positioned between the cluster module CM and the load port LP. In detail, the substrate cleaning device CD may be positioned between each of the substrate processing device and the main transfer robot R1, and the load port LP. More detailed information on the substrate cleaning device CD will be described later.

The load port LP may be coupled (e.g., physically coupled) to the substrate cleaning device CD. The substrate may be loaded on the load port LP. That is, the substrate may be selectively disposed on the load port LP. In detail, the substrate may be placed on the load port LP while being inserted into a front opening unified pod (FOUP) and/or a cassette. To fix the FOUP and/or the cassette to a certain position, the load port LP may include a plurality of pins. The substrate disposed on the load port LP may be transferred to the cluster module CM. The substrate placed on the load port LP may be transferred to the outside by an overhead hoist transfer (OHT) and/or an auto guided vehicle (AGV).

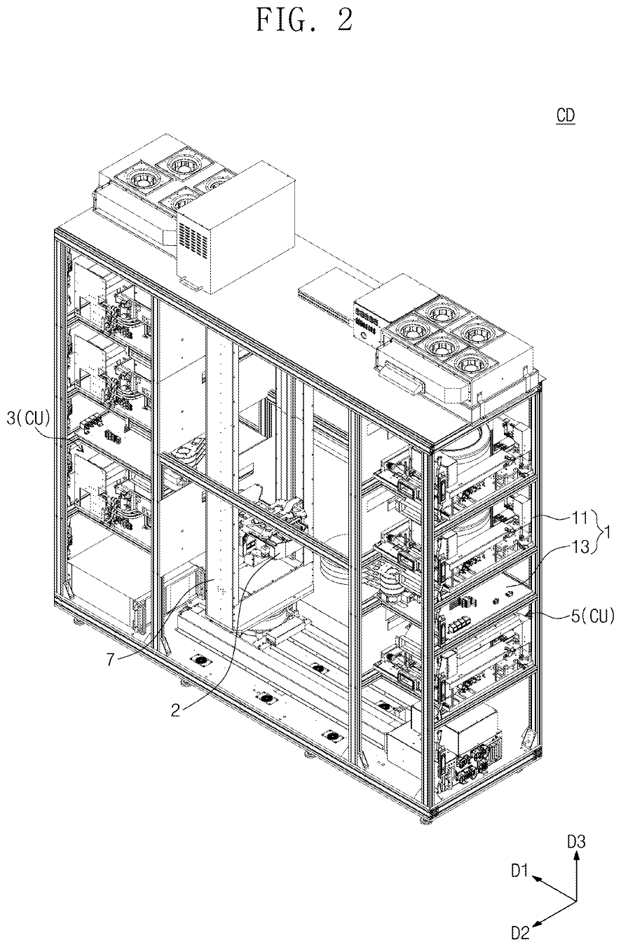

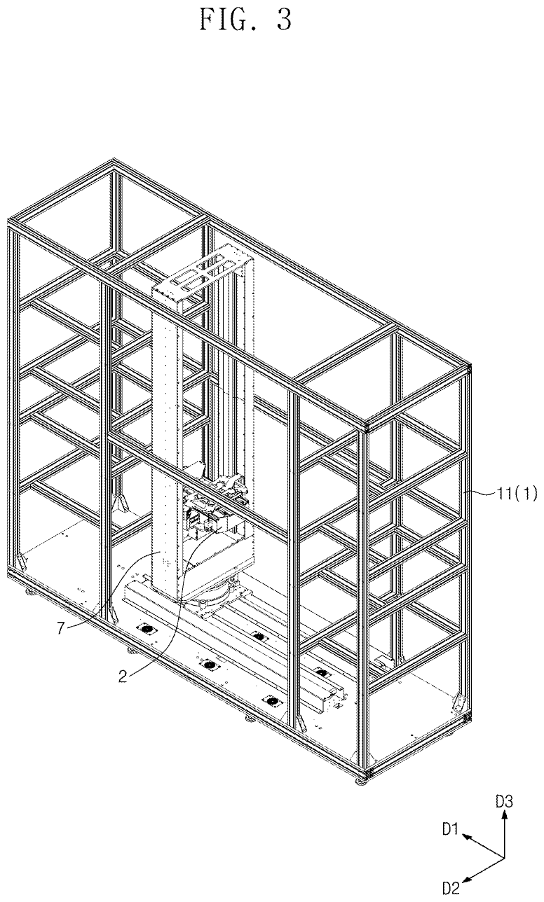

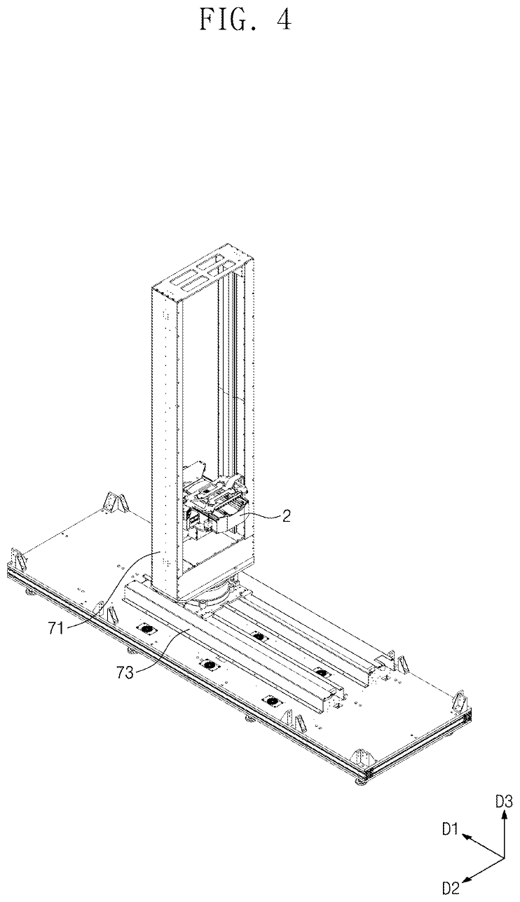

FIG. 2 is a perspective view illustrating the substrate cleaning device CD according to embodiments of the present disclosure, FIG. 3 is a perspective view illustrating a portion of the substrate cleaning device CD according to embodiments of the present disclosure, and FIG. 4 is a perspective view illustrating of a partial enlarged view of FIG. 3.

Referring to FIGS. 2 to 4, the substrate cleaning device CD may include a cleaning frame 1, a substrate cleaning unit CU (e.g., a substrate cleaner), a cleaning transfer robot 2, and an elevating device 7 (e.g., an elevator).

The cleaning frame 1 may include a support pillar 11 and a support plate 13. The support pillar 11 may extend vertically, e.g., in the third direction D3, and the support plate 13 may extend (e.g., lengthwise) horizontally, e.g., in the first direction D1. The support plate 13 may support the substrate cleaning unit CU. That is, the substrate cleaning unit CU may be disposed on the support plate 13. A plurality of support plates 13 may be provided, e.g., the plurality of support plates 13 may be provided among linear portions of the pillars 11. The plurality of support plates 13 may be vertically spaced apart from each other, e.g., in the third direction D3.

The substrate cleaning unit CU may be coupled to the cleaning frame 1. For example, the substrate cleaning unit CU may be disposed on the support plate 13. The substrate cleaning unit CU may perform a cleaning process on the substrate. The substrate cleaning unit CU may include a first substrate cleaning unit 3 and a second substrate cleaning unit 5. For example, the first substrate cleaning unit 3 may perform a cleaning process on a lower surface of the substrate. For example, the second substrate cleaning unit 5 may perform a cleaning process on an upper surface of the substrate. A plurality of first substrate cleaning units 3 may be provided. The plurality of first substrate cleaning units 3 may be stacked vertically, e.g., to vertically overlap each other. However, hereinafter, the first substrate cleaning unit 3 will be described in the singular. A plurality of second substrate cleaning units 5 may be provided. A plurality of second substrate cleaning units 5 may be stacked vertically, e.g., to vertically overlap each other. However, hereinafter, the second substrate cleaning unit 5 will be described in the singular. For example, each of the first substrate cleaning units 3 may be horizontally spaced apart from a corresponding one of the second substrate cleaning units 5. For example, the first substrate cleaning unit 3 may perform the cleaning process on the lower surface of the substrate, and the second substrate cleaning unit 5 may perform a cleaning process on the upper surface of the substrate. That is, one substrate cleaning device CD may perform the cleaning process on both the upper and lower surfaces of the substrate. More detailed information about the substrate cleaning device CD and the substrate cleaning unit CU will be described later.

The cleaning transfer robot 2 may transfer the substrate to the substrate cleaning unit CU, e.g., between horizontally spaced substrate cleaning units CU. To this end, the cleaning transfer robot 2 may include an arm capable of supporting the substrate.

The elevating device 7 may move the cleaning transfer robot up and down. The elevating device 7 may move the cleaning transfer robot 2 in a horizontal direction. For example, as illustrated in FIG. 4, the elevating device 7 may include an elevating frame 71 and a horizontal movement frame 73. The elevating frame 71 may extend vertically, e.g., in the third direction D3. The cleaning transfer robot 2 may move up and down along the elevating frame 71. The horizontal movement frame 73 may extend in a horizontal direction, e.g., in the first direction D1. The cleaning transfer robot 2 may move in a horizontal direction along the horizontal movement frame 73. For example, referring to FIG. 2, the cleaning transfer robot 2 may move along the horizontal movement frame 73 to move the substrate from the second substrate cleaning unit 5 (e.g., after the second substrate cleaning unit 5 cleaned the upper surface of the substrate) to the first substrate cleaning unit 3 (e.g., to clean the lower surface of the substrate). In another example, the substrate cleaning device CD may be configured to move the substrate from the first substrate cleaning unit 3 to the second substrate cleaning unit 5.

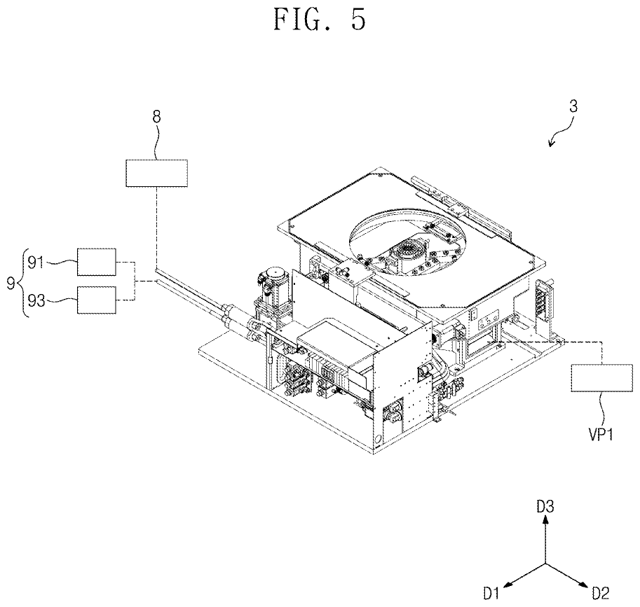

FIG. 5 is a perspective view illustrating the first substrate cleaning unit 3 according to embodiments of the present disclosure.

Referring to FIG. 5, the substrate cleaning device CD may further include a liquid supply device 8 (e.g., a liquid supplier), a gas supply device 9 (e.g., a gas supplier), and a vacuum pump VP1.

The liquid supply device 8 may supply liquid to the first substrate cleaning unit 3. For example, the liquid supply device 8 may supply de-ionized water (DIW) to the first substrate cleaning unit 3. To this end, the liquid supply device 8 may include a liquid tank, a liquid pipe, and/or a pump.

The gas supply device 9 may supply gas to the first substrate cleaning unit 3. The gas supply device 9 may supply two types of gas to the first substrate cleaning unit 3. For example, the gas supply device 9 may supply nitrogen (N₂) gas and carbon dioxide (CO₂) gas to the first substrate cleaning unit 3. To this end, the gas supply device 9 may include a nitrogen supply device 91 (e.g., a nitrogen supplier) and a carbon dioxide supply device 93 (e.g., a carbon supplier). The nitrogen supply device 91 may supply nitrogen (N₂) gas to the first substrate cleaning unit 3. To this end, the nitrogen supply device 91 may include a nitrogen tank, a nitrogen pipe, and/or a compressor. The carbon dioxide supply device 93 may supply carbon dioxide (CO₂) gas to the first substrate cleaning unit 3. To this end, the carbon dioxide supply device 93 may include a carbon dioxide tank, a carbon dioxide pipe, and/or a compressor.

The vacuum pump VP1 may provide vacuum pressure to the first substrate cleaning unit 3. The liquid and/or gas supplied to the first substrate cleaning unit 3 may be discharged from the first substrate cleaning unit 3 by the vacuum pressure provided through the vacuum pump VP1. More detailed information about the vacuum pump VP1 will be described later.

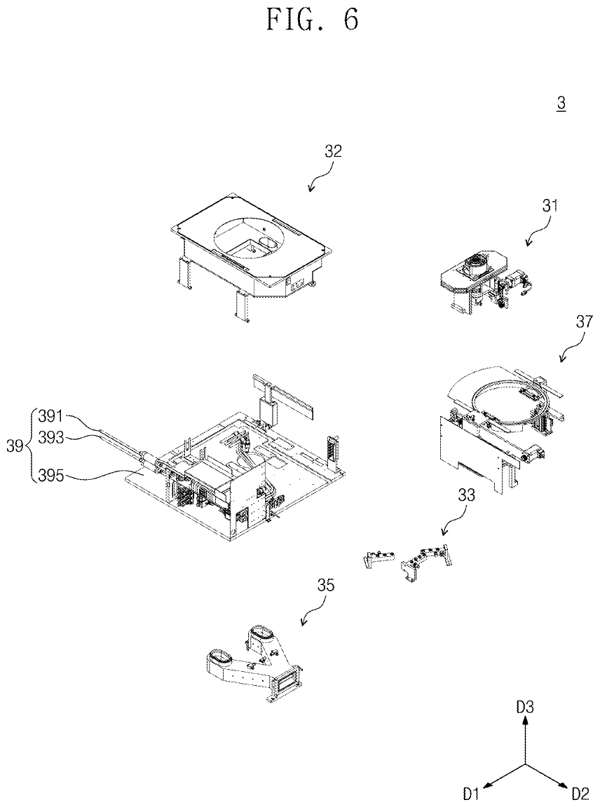

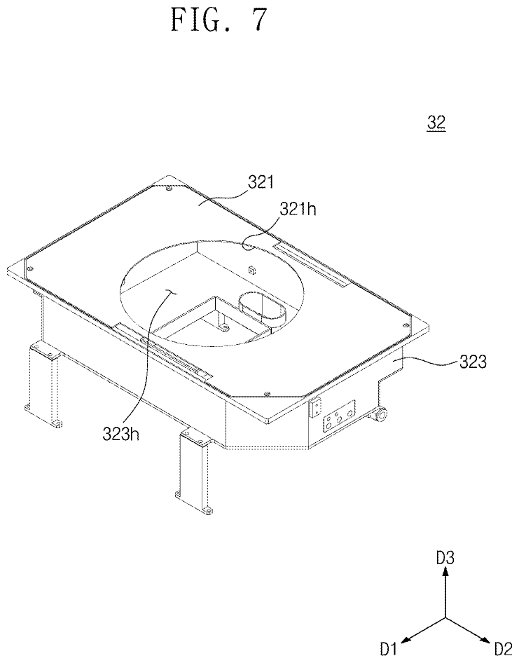

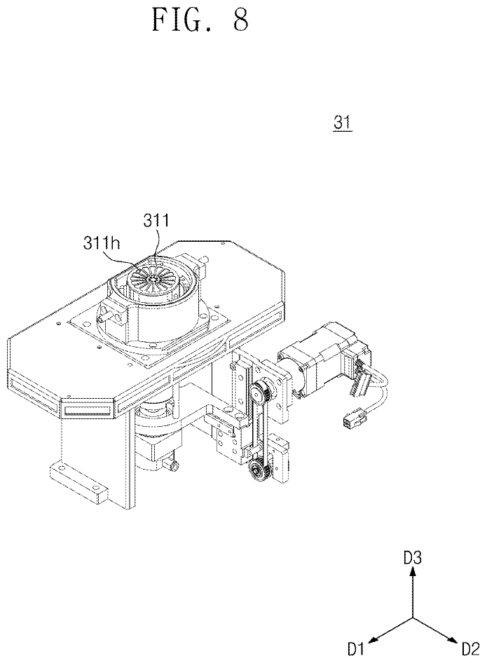

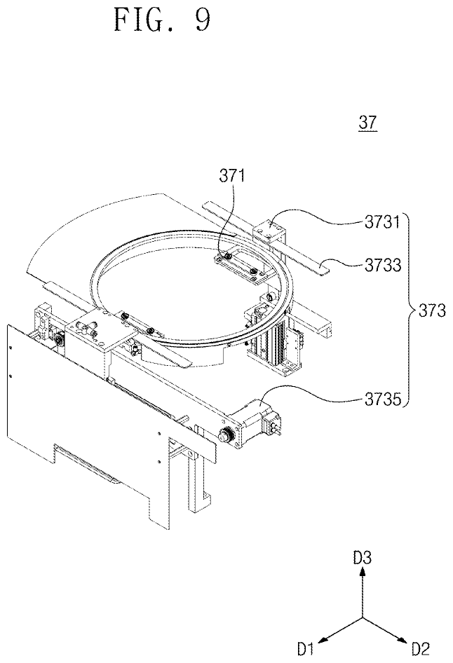

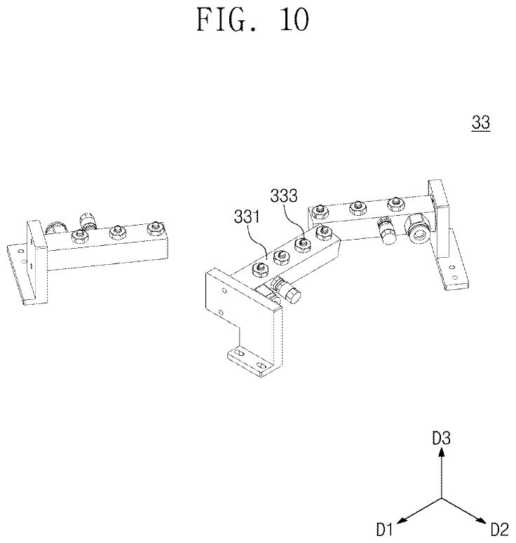

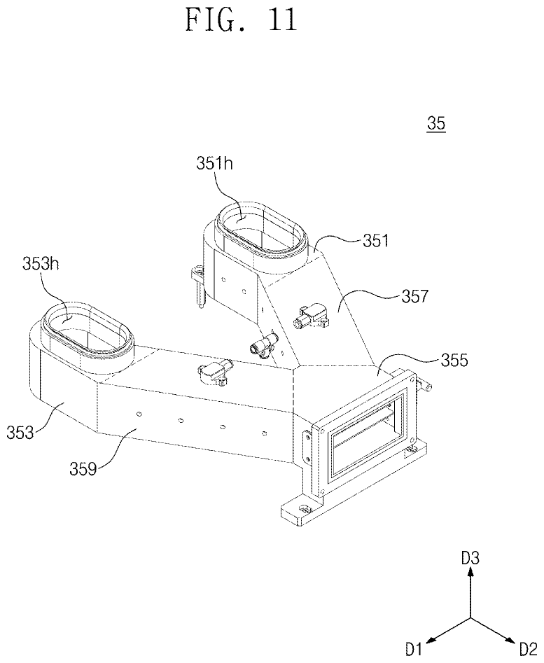

FIG. 6 is an exploded perspective view illustrating the first substrate cleaning unit 3 according to embodiments of the present disclosure, FIG. 7 is an exploded perspective view illustrating a portion (a cleaning housing) of the first substrate cleaning unit 3 according to embodiments of the present disclosure, FIG. 8 is an exploded perspective view illustrating a portion (a cleaning chuck) of the first substrate cleaning unit 3 according to embodiments of the present disclosure, FIG. 9 is an exploded perspective view illustrating a portion (a substrate moving device) of the first substrate cleaning unit 3 according to embodiments of the present disclosure, FIG. 10 is an exploded perspective view illustrating a portion (a lower cleaning nozzle) of a substrate cleaning unit according to embodiments of the present disclosure, and FIG. 11 is an exploded perspective view illustrating a portion (an intake device) of a substrate cleaning unit according to embodiments of the present disclosure.

Referring to FIG. 6, the first substrate cleaning unit 3 may include a cleaning body 39, a cleaning housing 32, a cleaning chuck 31, a lower cleaning nozzle 33, an intake device 35 (e.g., an intaker), and a substrate moving device 37 (e.g., a substrate mover).

Referring to FIGS. 5 and 6, the cleaning body 39 may include a base 395, a first pipe 391, and a second pipe 393. The base 395 may support the cleaning housing 32 or the like. A first end of the first pipe 391 may be connected to the liquid supply device 8. A second end of the first pipe 391 may be connected to a lower cleaning nozzle 33. DIW supplied from the liquid supply device 8 may move to the lower cleaning nozzle 33 along the first pipe 391. A first end of the second pipe 393 may be connected to the gas supply device 9. A second end of the second pipe 393 may be connected to the lower cleaning nozzle 33. The gas supplied from the gas supply device 9 may move to the lower cleaning nozzle 33 along the second pipe 393.

Referring to FIGS. 6 and 7, the cleaning housing 32 may include a housing body 323 and an upper plate 321. The housing body 323 may be coupled onto the base 395. The housing body 323 may provide an inner space 323h. The upper plate 321 may be coupled to the housing body 323. The upper plate 321 may provide substrate placement holes 321h. For example, the substrate placement hole 321h may have a circular shape when viewed in a plan view. The inner space 323h may be exposed by the substrate placement hole 321h.

Referring to FIGS. 6 and 8, the cleaning chuck 31 may include a chuck body 311. The chuck body 311 may provide a chucking hole 311h. The chucking hole 311h may be connected to a chucking pump. The substrate may be fixed on the chuck body 311 by vacuum pressure applied to the chucking hole 311h from the chucking pump.

Referring to FIGS. 6 and 9, the substrate moving device 37 may include an edge chuck 371 and a chuck driving device 373 (e.g., a chuck driver). The edge chuck 371 may be positioned outside the cleaning chuck 31. The edge chuck 371 may fix the substrate by vacuum pressure. While the vacuum pressure is released from the cleaning chuck 31, the substrate may be fixed on the edge chuck 371 by the vacuum pressure applied to the edge chuck 371. The chuck driving device 373 may include a support member 3731 (e.g., a supporter), a guide member 3737 (e.g., a guide), and a driving motor 3735. The support member 3731 may be fixedly coupled to the edge chuck 371. The support member 3731 may be movable in a horizontal direction. The guide member 3737 may extend in a horizontal direction. The guide member 3737 may guide the movement of the support member 3731. The support member 3731 may move in a horizontal direction along the guide member 3737. The driving motor 3735 may provide power so that the support member 3731 moves along the guide member 3737.

Referring to FIGS. 6 and 10, the lower cleaning nozzle 33 may include a nozzle body 331 and a nozzle 333. The nozzle body 331 may extend in a horizontal direction. The nozzle 333 may be coupled onto the nozzle body 331. A plurality of nozzles 333 may be provided. The plurality of nozzles 333 may be arranged, e.g., spaced apart, in a horizontal direction on one nozzle body 331. A plurality of nozzle bodies 331 may be provided. The plurality of nozzle bodies 331 may be spaced apart from each other in a horizontal direction.

Referring to FIGS. 6 and 11, the intake device 35 may be positioned below the upper plate 321 of the cleaning housing 32 (refer to FIG. 7). The intake device 35 may include a first duct 351, a second duct 353, a main duct 355, a first connection duct 357, and a second connection duct 359.

The first duct 351 may provide a first intake port 351h. The first intake port 351h may face the substrate placement hole 321h of the cleaning housing 32 (refer to FIG. 7).

The second duct 353 may provide a second intake port 353h. The second intake port 353h may face the substrate placement hole 321h of the cleaning housing 32. The second duct 353 may be spaced apart from the first duct 351 in the first direction D1.

The main duct 355 may be spaced apart from each of the first duct 351 and the second duct 353 in the second direction D2. The main duct 355 may be connected to the vacuum pump VP1 (refer to FIG. 5). A fluid in the inner space 323h of the cleaning housing 32 (see FIG. 7) may be discharged to the outside by the vacuum pressure provided from the vacuum pump VP1.

The first connection duct 357 may connect the first duct 351 and the main duct 355. The first connection duct 357 may extend to form an oblique (e.g., acute) angle with the first direction D1.

The second connection duct 359 may connect the second duct 353 and the main duct 355. The second connection duct 359 may extend to form an oblique (e.g., acute) angle with the first direction D1. The second connection duct 359 and the first connection duct 357 may be symmetrical to each other with respect to an imaginary line segment extending in the second direction D2 through a enter of the main duct 355.

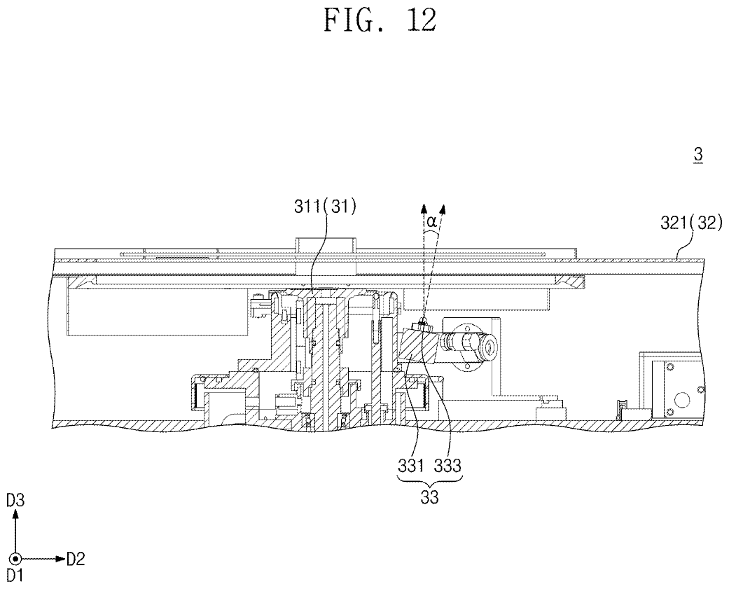

FIG. 12 is a cross-sectional view illustrating a portion of the substrate cleaning unit 3 according to embodiments of the present disclosure.

Referring to FIG. 12, the nozzle 333 may be disposed in an inclined state. For example, the nozzle 333 may be inclined so that a flow direction of a fluid ejected from the nozzle 333 forms an acute angle ‘α’ with the third direction D3.

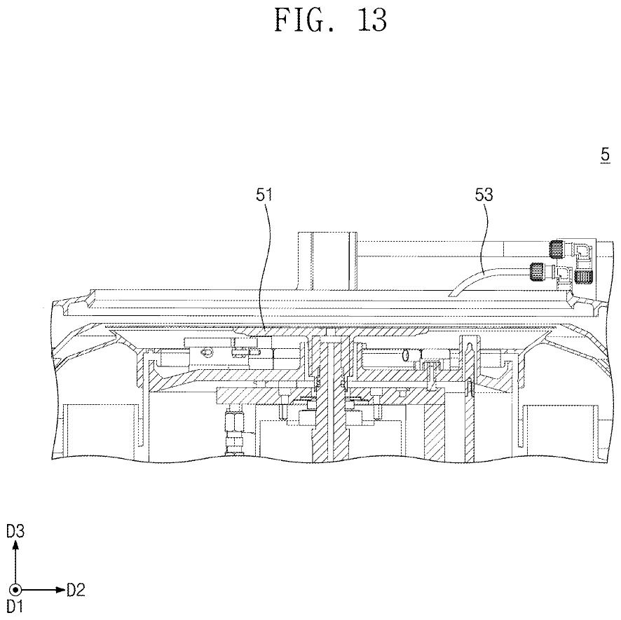

FIG. 13 is a cross-sectional view illustrating a portion of the substrate cleaning unit 5 according to embodiments of the present disclosure.

Referring to FIG. 13, the second substrate cleaning unit 5 may include a cleaning chuck 51 and an upper cleaning nozzle 53. The cleaning chuck 51 may be substantially the same as or similar to the cleaning chuck 31 described with reference to FIG. 8. The upper cleaning nozzle 53 may be spaced upwardly from the cleaning chuck 51. The upper cleaning nozzle 53 may spray fluid to an upper surface of the substrate disposed on the cleaning chuck 51.

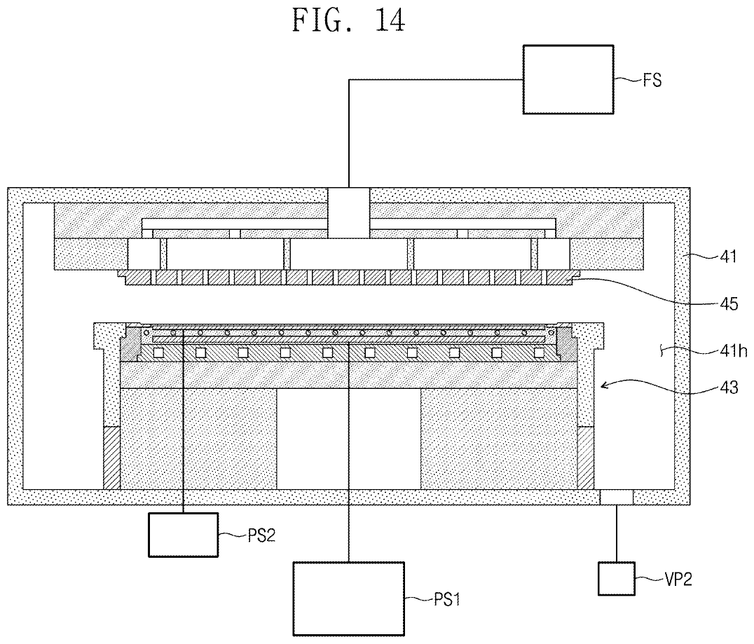

FIG. 14 is a cross-sectional view illustrating the substrate processing device SC according to embodiments of the present disclosure.

Referring to FIG. 14, the substrate processing device SC (refer to FIG. 1) may include an etching chamber. In this case, the substrate processing device SC may include an etching housing 41, an etching chuck 43, a shower head 45, a fluid supplier FS, a first power supplier PS1, a second power supplier PS2, and a second vacuum pump VP2.

The etching housing 41 may provide an etching space 41h. The etching chuck 43 may be positioned in the etching space 41h. The etching chuck 43 may support and/or hold a substrate. The shower head 45 may be spaced upwardly from the etching chuck 43. The fluid supplier FS may supply fluid to the etching space 41h. The fluid supplier FS may be connected to the etching space 41h through the shower head 45. The first power supplier PS1 may supply first power to the etching chuck 43. The first power may be, e.g., radiofrequency (RF) power. The second power supplier PS2 may supply second power to the etching chuck 43. The second power may be, e.g., direct current (DC) power. The second vacuum pump VP2 may provide vacuum pressure to the etching space 41h.

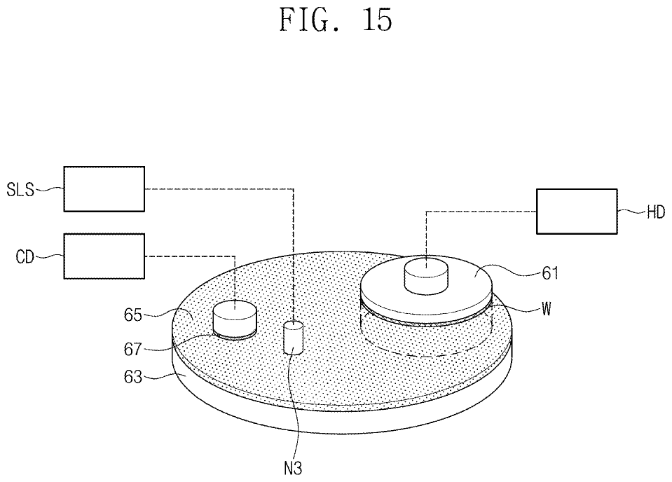

FIG. 15 is a perspective view illustrating the substrate processing device SC according to embodiments of the present disclosure.

Referring to FIG. 15, the substrate processing device SC (refer to FIG. 1) may include a polishing chamber. In this case, the substrate processing device SC may include a polishing head 61, a polishing stage 63, a polishing pad 65, a conditioning disk 67, a head driver HD, a conditioning driver CD, a slurry supplier SLS, and a polishing nozzle N3.

The polishing head 61 may support a substrate W. The substrate W supported by the polishing head 61 may be polished by the polishing pad 65. The polishing stage 63 may rotate the polishing pad 65. The polishing pad 65 may come into contact with the substrate W to polish one surface of the substrate W. The conditioning disk 67 may improve the condition of an upper surface of the polishing pad 65. For example, the conditioning disk 67 may polish the upper surface of the polishing pad 65. The head driver HD may rotate and/or move the polishing head 61 in parallel. The conditioning driver CD may move the conditioning disk 67. The slurry supplier SLS may supply slurry to the polishing nozzle N3. The polishing nozzle N3 may be connected to the slurry supplier SLS. The polishing nozzle N3 may spray the slurry supplied from the slurry supplier SLS to the polishing pad 65.

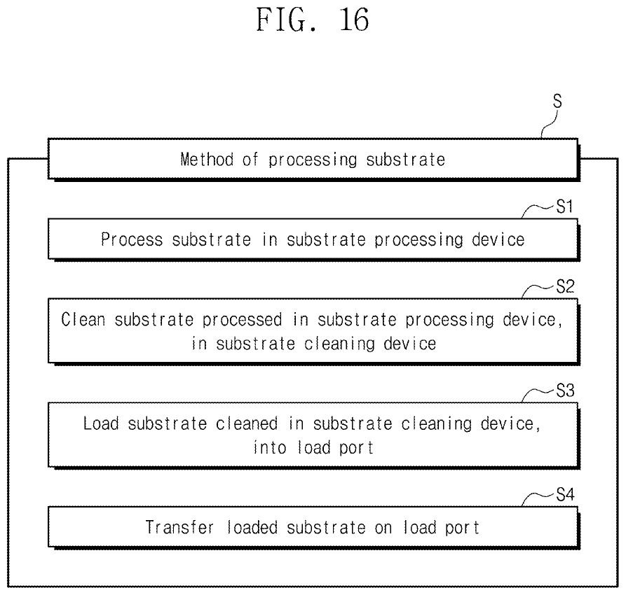

FIG. 16 is a flowchart illustrating a method of processing a substrate according to embodiments of the present disclosure.

Referring to FIG. 16, a method of processing a substrate may be provided. The method of processing the substrate may be a method of processing a substrate using the substrate processing system SY (refer to FIG. 1) described with reference to FIGS. 1 to 15. The method of processing a substrate may include processing a substrate in a substrate processing device (S1), cleaning the substrate, which is processed in the substrate processing device, in a substrate cleaning device (S2), loading the substrate, which is cleaned in the substrate cleaning device, on a load port (S3), and transferring the substrate loaded on the load port (S4).

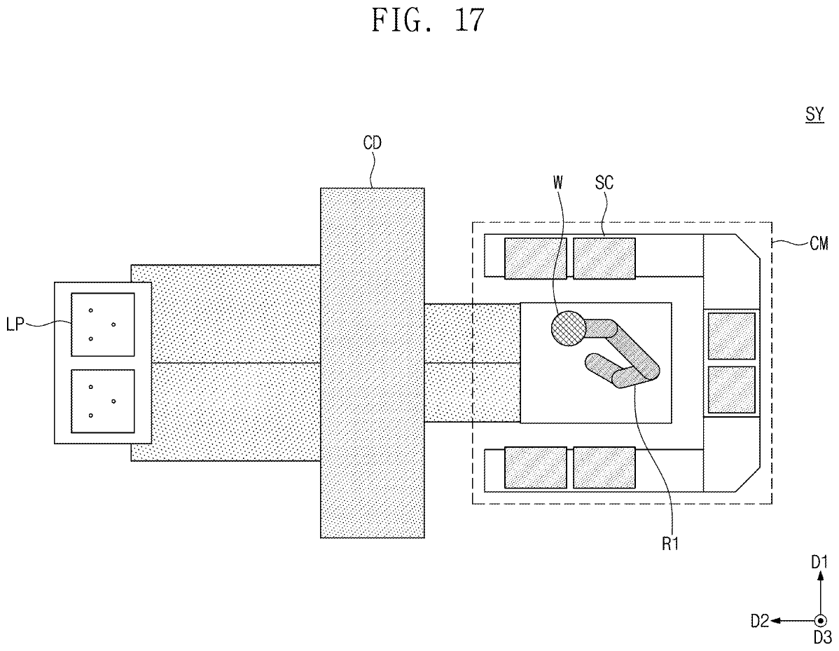

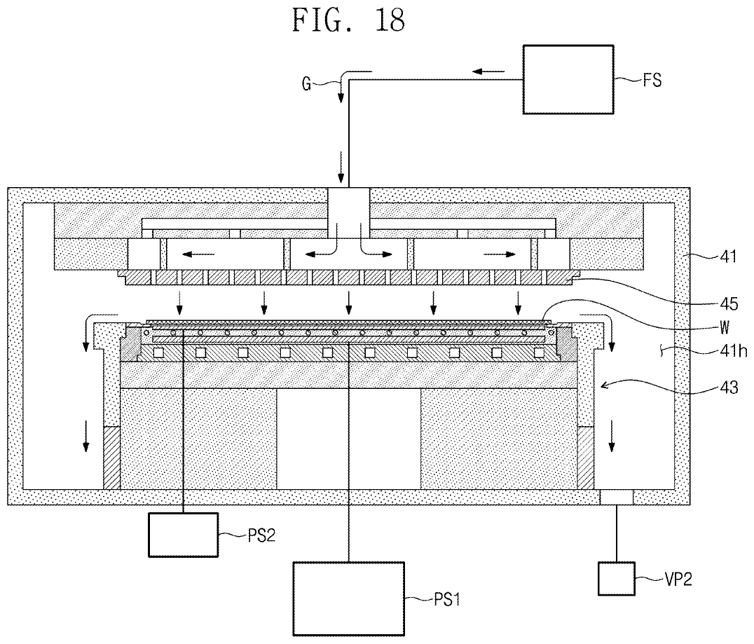

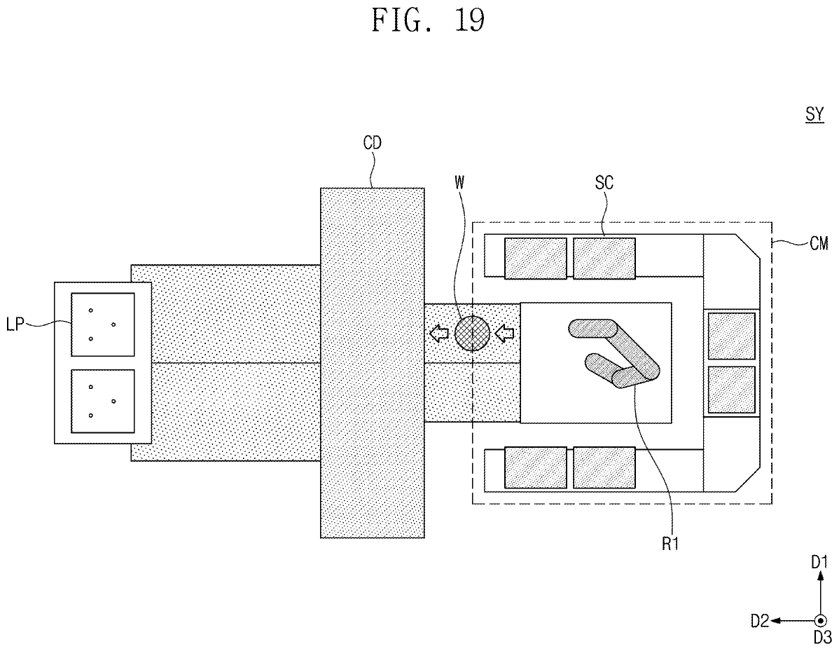

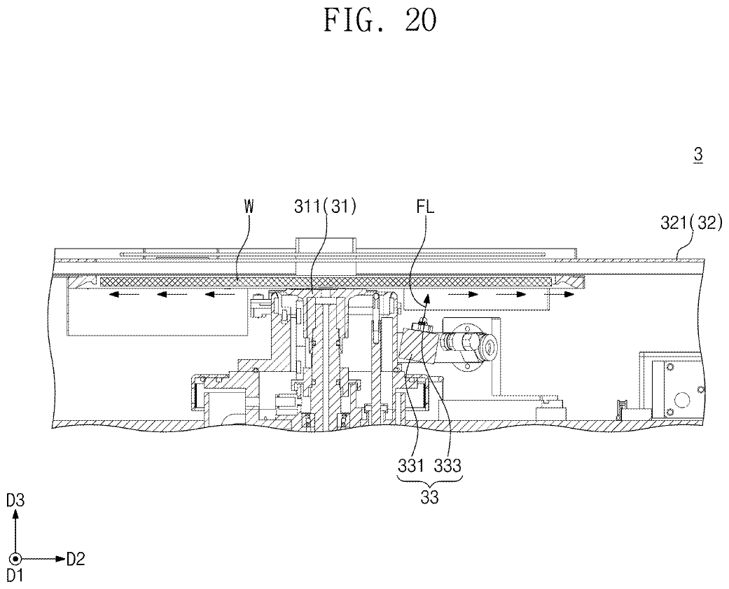

Hereinafter, the method of processing a substrate of FIG. 16 will be described in detail with reference to FIGS. 17 to 21. FIGS. 17 to 21 are diagrams illustrating stages in a method of processing a substrate according to the flowchart of FIG. 16.

Referring to 16-18, processing the substrate in the substrate processing device in S1 may include placing the substrate W in the substrate processing devices SC by the main transfer robot R1. When the substrate processing device SC is an etching chamber, the substrate W may be disposed on the etching chuck 43. The etching process for the substrate W on the etching chuck 43 may be performed by gas G supplied to the etching space 41h through the fluid supplier FS. In this process, contaminants, e.g., particles, may be generated on the substrate W. For example, processing the substrate W may include performing an etching process on the substrate W. In another example, processing the substrate W in the substrate processing device SC may include performing one of a polishing process and a deposition process on the substrate W.

Referring to FIGS. 16, 19, and 20, cleaning the processed substrate W in the substrate processing device in the substrate cleaning device in S2 may include placing the substrate W in the substrate cleaning unit CU by the main transfer robot R1, the cleaning transfer robot 2 (refer to FIG. 4), and/or the elevating device 7 (refer to FIG. 4). That is, the processed substrate W in the substrate processing device SC may be cleaned in the substrate cleaning device CD before moving to the load port LP. For example, a fluid FL may be sprayed to the substrate W disposed on the cleaning chuck 31. The fluid FL may be sprayed to a lower surface of the substrate W by the lower cleaning nozzle 33. For example, once the lower surface of the substrate W is cleaned by the lower cleaning nozzle 33 in the first substrate cleaning unit 3, the cleaning transfer robot 2 may transfer the substrate W to the second substrate cleaning unit 5 to clean the upper surface of the substrate W, before being transferred to the load port LP, e.g., by the main transfer robot R1.

In detail, a two-fluid mixture of liquid and gas may be sprayed onto the substrate W, e.g., the lower surface of the substrate W. The gas sprayed onto the lower surface of the substrate W may include nitrogen (N₂) and/or carbon dioxide (CO₂). When carbon dioxide (CO₂) is sprayed to the substrate W, static electricity on the substrate W may be prevented or substantially minimized. That is, when carbon dioxide (CO₂), which has a higher ionization tendency than nitrogen (N₂), is sprayed to the substrate W, static electricity of the substrate W may be prevented or substantially minimized. For example, fluid, e.g., the two-fluid mixture, may also be sprayed to an upper surface of the substrate W.

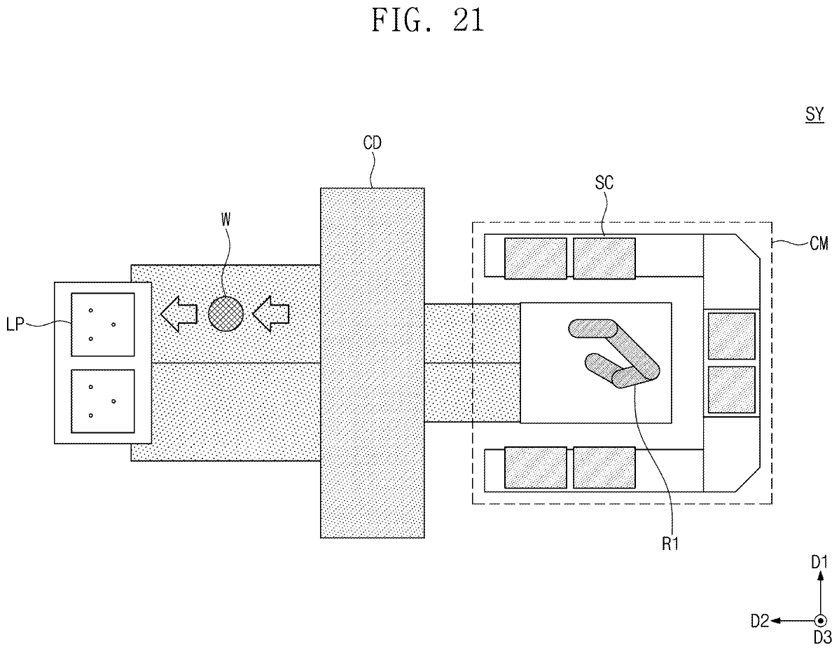

Referring to FIGS. 16 and 21, loading the cleaned substrate in the substrate cleaning device on the load port in S3 may include placing the substrate W, that is passed through the substrate cleaning device CD, on the load port LP. Transferring the substrate W loaded on the load port S4 may include transferring the substrate W to the outside. For example, an overhead hoist transfer (OHT) or an auto guided vehicle (AGV) may pick up the substrate W loaded on the load port LP and transfer the substrate W to the outside.

According to a substrate cleaning device according to embodiments of the present disclosure, a substrate processing system including the same, and a method of processing a substrate using the same, contaminants such as particles remaining on the substrate processed in the substrate processing device may be removed from the substrate before the substrate is loaded on the load port. Accordingly, contaminants such as particles on the substrate may be prevented from moving to other locations. Therefore, contamination may be prevented or substantially minimized from spreading.

According to a substrate cleaning device according to embodiments of the present disclosure, a substrate processing system including the same, and a method of processing a substrate using the same, the substrate using carbon dioxide may be cleaned using carbon dioxide, thereby preventing static electricity on the substrate. That is, carbon dioxide, which has a higher ionization tendency than nitrogen, may be in contact with the substrate, thereby preventing the static electricity on the substrate.

According to a substrate cleaning device according to embodiments of the present disclosure, a substrate processing system including the same, and a method of processing a substrate using the same, the plurality of substrate cleaning units may be stacked vertically. Accordingly, a volume of the entire substrate processing system may be reduced.

According to example embodiments, the substrate may be cleaned before the substrate passing through the substrate processing device is transferred. Further, it is possible to prevent the spread of contamination caused by particles or the like generated in the substrate processing device. Furthermore, static electricity may be prevented during the cleaning process. In addition, the overall volume of the system may be reduced.

By way of summation and review, aspects of embodiments provide a substrate cleaning device capable of cleaning a substrate before transferring a substrate that has passed through a substrate processing device, a substrate processing system including the same, and a method of processing a substrate using the same. aspects of embodiments also provide a substrate cleaning device capable of preventing spread of contamination caused by particles generated in a substrate processing device, a substrate processing system including the same, and a method of processing a substrate using the same. In addition, aspects of embodiments provide a substrate cleaning device capable of preventing static electricity during a cleaning process, a substrate processing system including the same, and a method of processing a substrate using the same. Also, aspects of embodiments provide a substrate cleaning device capable of reducing a volume of the entire system, a substrate processing system including the same, and a method of processing a substrate using the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate processing system, comprising:
a cluster module having substrate processing devices;
a load port through which a substrate is loaded; and
a substrate cleaning device between the cluster module and the load port, the substrate cleaning device being configured to clean the substrate processed in the substrate processing devices, and the substrate cleaning device including at least one substrate cleaner having a cleaning chuck to support the substrate and a cleaning nozzle configured to spray a fluid toward the cleaning chuck.

2. The substrate processing system as claimed in claim 1, wherein the cleaning nozzle includes a lower cleaning nozzle below the cleaning chuck.

3. The substrate processing system as claimed in claim 2, wherein the substrate cleaning device further includes:
a liquid supplier connected to the lower cleaning nozzle, the liquid supplier being configured to supply liquid to the lower cleaning nozzle; and
a gas supplier connected to the lower cleaning nozzle, the gas supplier being configured to supply gas to the lower cleaning nozzle.

4. The substrate processing system as claimed in claim 1, wherein:
the substrate cleaning device further includes support plates vertically spaced apart from each other, and
the at least one substrate cleaner includes a plurality of substrate cleaners on the support plates.

5. The substrate processing system as claimed in claim 4, wherein the substrate cleaning device further includes:
a cleaning transfer robot configured to transfer the substrate to each of the plurality of substrate cleaners; and
an elevator configured to move the cleaning transfer robot up and down.

6. The substrate processing system as claimed in claim 1, wherein the cluster module further includes a main transfer robot configured to transfer the substrate processed in the substrate processing devices to the substrate cleaning device, the substrate cleaning device being between the main transfer robot and the load port.

7. The substrate processing system as claimed in claim 1, wherein each of the substrate processing devices includes at least one of an etching chamber, a polishing chamber, and a deposition chamber.

8. A substrate processing system with a substrate cleaning apparatus, the substrate cleaning apparatus comprising:
a substrate cleaner, the substrate cleaner including:
a cleaning chuck configured to support a substrate, and
a lower cleaning nozzle configure to spray fluid toward the cleaning chuck;
a liquid supplier configured to supply de-ionized water to the substrate cleaner; and
a gas supplier configured to supply gas to the substrate cleaner, the gas supplier including:
a nitrogen supplier connected to the lower cleaning nozzle and configured to supply nitrogen to the lower cleaning nozzle, and
a carbon dioxide supplier connected to the lower cleaning nozzle and configured to supply carbon dioxide to the lower cleaning nozzle.

9. The substrate processing system as claimed in claim 8, wherein:
the substrate cleaner further includes a substrate mover configured to move the substrate in the substrate cleaner in a horizontal direction,
the substrate mover including:
an edge chuck outside the cleaning chuck, and
a chuck driver configured to move the edge chuck relative to the cleaning chuck in the horizontal direction.

10. The substrate processing system as claimed in claim 9, wherein the chuck driver includes:
a supporter coupled to the edge chuck and movable in the horizontal direction;
a guide extending in the horizontal direction and configured to guide movement of the supporter; and
a drive motor configured to provide power to move the supporter along the guide.

11. The substrate processing system as claimed in claim 8, wherein the substrate cleaner further includes:
an upper plate having a substrate placement hole, the cleaning chuck being exposed by the substrate placement hole; and
an intaker under the upper plate.

12. The substrate processing system as claimed in claim 11, wherein the intaker includes:
a first duct including a first intake port oriented toward the substrate placement hole;
a second duct including a second intake port oriented toward the substrate placement hole and spaced apart from the first duct in a first horizontal direction;
a main duct spaced apart from each of the first duct and the second duct in a second horizontal direction crossing the first horizontal direction;
a first connection duct connecting the first duct and the main duct, the first connection duct extending at an acute angle with respect to the first horizontal direction; and
a second connection duct connecting the second duct and the main duct.

13. The substrate processing system as claimed in claim 8, wherein the substrate cleaner further includes an upper cleaning nozzle spaced upwardly from the cleaning chuck.

14. The substrate processing system as claimed in claim 8, further comprising:
a cluster module having substrate processing devices; and
a load port through which the substrate is loaded, the substrate cleaning apparatus being positioned between the cluster module and the load port.

15. The substrate processing system as claimed in claim 14, wherein each of the substrate processing devices includes at least one of an etching chamber, a polishing chamber, and a deposition chamber.

16. The substrate processing system as claimed in claim 8, wherein:
the substrate cleaning apparatus further includes support plates vertically spaced apart from each other, and
the at least one substrate cleaner includes a plurality of substrate cleaners on the support plates.

17. The substrate processing system as claimed in claim 2, wherein the cleaning nozzle includes an upper cleaning nozzle spaced upwardly from the cleaning chuck.

18. The substrate processing system as claimed in claim 1, wherein:
the substrate cleaner further includes a substrate mover configured to move the substrate in the substrate cleaner in a horizontal direction, and
the substrate mover includes:
an edge chuck outside the cleaning chuck, and
a chuck driver configured to move the edge chuck relative to the cleaning chuck in the horizontal direction.

19. The substrate processing system as claimed in claim 18, wherein the chuck drive includes:
a supporter coupled to the edge chuck and movable in the horizontal direction;
a guide extending in the horizontal direction and configured to guide movement of the supporter; and
a drive motor configured to provide power to move the supporter along the guide.

20. The substrate processing system as claimed in claim 3, wherein the gas supplier includes:
a nitrogen supplier connected to the lower cleaning nozzle and configured to supply nitrogen to the lower cleaning nozzle; and
a carbon dioxide supplier connected to the lower cleaning nozzle and configured to supply carbon dioxide to the lower cleaning nozzle.
